(19) United States
(12) Patent Application Publication
(10) Pub. No.: US 2007/0090356 A1
(43) Pub. Date: Apr. 26, 2007

(54) SEMICONDUCTOR DEVICE

(75) Inventor: Terunao HANAOKA, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 11/550,992

(22) Filed: Oct. 19, 2006

(30) Foreign Application Priority Data
Oct. 21, 2005 (JP) 2005-306953

(51) Int. Cl. H01L 23/58

(52) U.S. Cl. 257/48

(57) ABSTRACT

A semiconductor device includes a semiconductor substrate having electrodes, a resin layer provided on the surface of the semiconductor substrate on which the electrodes are formed and having concave portions formed on a second surface on the other side of a first surface facing the semiconductor substrate, test pads electrically connected to the electrode and formed inside the concave portion, wirings electrically connected to the test pad, going through on the second surface of the resin layer, and narrower in width than the test pad, and lands electrically connected to any one of the test pads and having an external terminal formed thereon.

The entire disclosure of Japanese Patent Application No. 2005-306953, filed Oct. 21, 2005 is expressly incorporated by reference herein.

### BACKGROUND

1. Technical Field

The present invention relates to a semiconductor device.

2. Related Art

As development of a semiconductor device having miniaturization potential proceeds, it is important to secure the reliability of such a semiconductor device at the same time. To secure the reliability of the semiconductor device, it is important to conduct an electrical property test on the semiconductor device. Currently the probe test is known as a method of conducting an electrical property test on a semiconductor device. This is a test method in which electrical properties are tested by making a test needle called ‘probe’ touch the test object. To conduct a reliable probe test, it is preferable that the area of the object to be touched by the probe be wide.

WO 01/71805 is an example of related art.

### SUMMARY

An advantage of the invention is to provide a semiconductor device having miniaturization potential as well as high reliability.

According to a first aspect of the invention, a semiconductor device includes a semiconductor substrate having an electrode, a resin layer provided on the surface of the semiconductor substrate on which the electrode is formed and having a concave portion formed on a second surface on the other side of a first surface facing the semiconductor substrate, a test pad electrically connected to the electrode and formed inside the concave portion, wiring electrically connected to the test pad, going through on the second surface of the resin layer, and narrower in width than the test pad, and a land electrically connected to the test pads and having an external terminal formed thereon. According to the invention, even when the electrode is made smaller in outside dimensions, it is easy to conduct an electrical property test. This allows providing a semiconductor device having miniaturization potential as well as high reliability.

According to a second aspect of the invention, a semiconductor device includes a semiconductor substrate having an electrode, a resin layer provided on the surface of the semiconductor substrate on which the electrode is formed and having holes on a second surface on the other side of a first surface facing the semiconductor substrate, a test pad electrically connected to the electrode and formed inside the holes, wiring electrically connected to the test pads, going through on the second surface of the resin layer, and narrower in width than the test pad, and a land electrically connected to the test pad and having an external terminal formed thereon. According to the invention, even when the electrode is made smaller in outside dimensions, it is easy to conduct an electrical property test. This allows providing a semiconductor device having miniaturization potential as well as high reliability.

In the semiconductor device according to the first aspect of the invention, the test pad may be larger than the electrode in outside dimensions.

The semiconductor device according to the first aspect of the invention may further include a resist layer having an opening for exposing the test pad formed thereon.

The semiconductor device according to the first aspect of the invention may further include coating portion for covering an exposed portion of the test pad at the opening.

In the semiconductor device according to the first aspect of the invention, the land may be provided between the test pad and the electrode.

In the semiconductor device according to the first aspect of the invention, the test pad may be provided between the land and the electrode.

### BRIEF DESCRIPTION OF THE DRAWINGS

FIGS. 1A to 1C show a semiconductor device according to an embodiment of the invention.

FIGS. 2A and 2B show a semiconductor device according to the embodiment of the invention.

FIG. 3 shows a semiconductor device according to the embodiment of the invention.

FIG. 4 shows a circuit board on which a semiconductor device according to the embodiment of the invention is mounted.

FIG. 5 shows an electronic device that includes a semiconductor device according to the embodiment of the invention.

FIG. 6 shows an electronic device that includes a semiconductor device according to the embodiment of the invention.

FIGS. 7A and 7B show a semiconductor device according to a modification of the embodiment of the invention.

### DESCRIPTION OF EXEMPLARY EMBODIMENTS

Hereafter, an embodiment according to the invention is described referring to the attached drawings. However, the invention is not limited to the embodiment. The invention includes free combinations of the following contents.

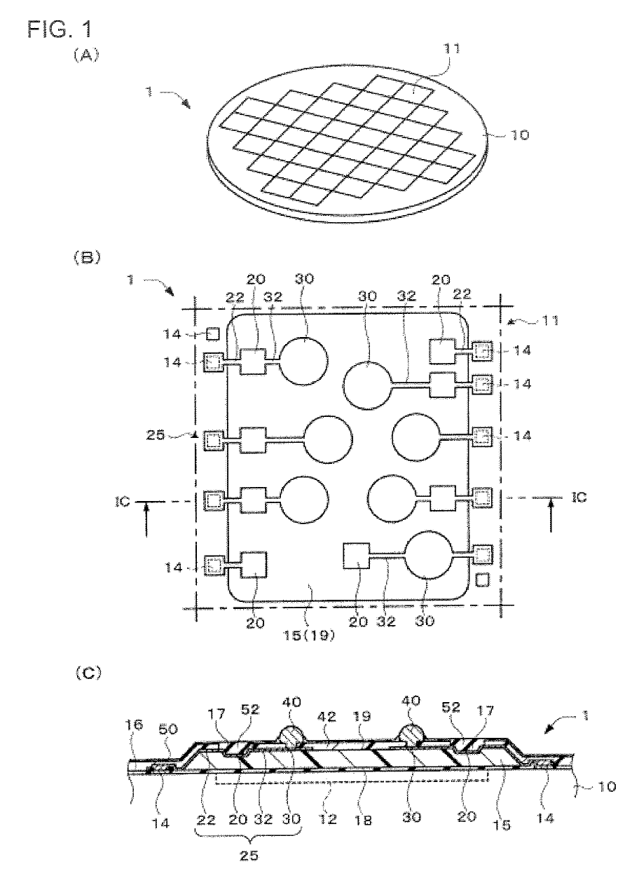

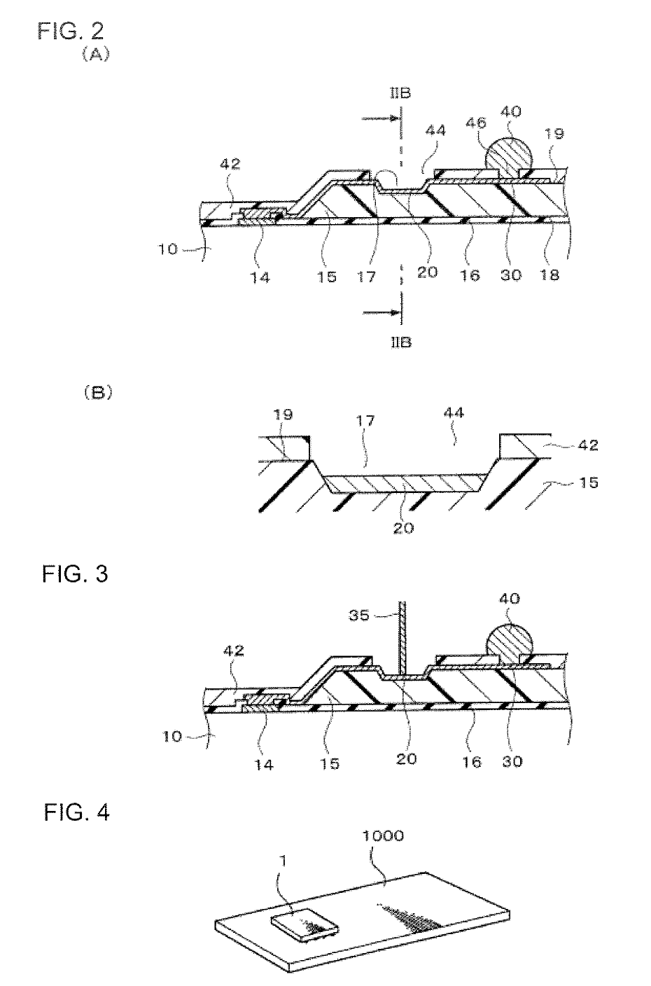

FIGS. 1A to 6 show semiconductor devices according to the embodiment of the invention. FIG. 1A is a schematic view of a semiconductor device 1. FIG. 1B is a top view showing a part of the semiconductor device 1. FIG. 1C is a partial enlarged view of a cross section IC-IC of FIG. 1B. Note that in FIG. 1B an external terminal 40, a resist layer 42, and a reinforcement layer 50 are omitted for explanation. FIG. 2A is a partial enlarged view of FIG. 1C but the reinforcement layer 50 (a coating portion 52) is omitted for explanation. FIG. 2B is a partial enlarged view of a cross section IIB-IIB of FIG. 2A.

A semiconductor device according to the embodiment has a semiconductor substrate 10. The semiconductor substrate 10 may be, for example, a silicon substrate. The semiconductor substrate 10 may be wafer-shaped (see FIG. 1A). That is, the semiconductor substrate 10 may be a semiconductor wafer. The wafer-shaped semiconductor substrate 10 may include areas 11 that become plural semiconductor devices. The semiconductor substrate 10 may be chip-shaped (not shown).

The semiconductor substrate 10 has one or plural integrated circuit 12 (one for a semiconductor chip; plural for a semiconductor wafer) (see FIG. 1C). The integrated circuit 12 may be formed for each area 11. The configuration of the integrated circuit 12 is not limited. It may include, for example, an active element, such as transistor, or a passive element, such as resistance, coil, or capacitor.

The semiconductor substrate 10 has plural electrodes 14, as shown in FIGS. 1B and 1C. The electrodes 14 may be formed on the surface on which the integrated circuit 12 is formed. The electrodes 14 may be electrically connected to the interior of the semiconductor substrate 10. The electrodes 14 may be electrically connected to the integrated circuit 12. The electrodes 14 may include electrodes not electrically connected to the integrated circuit 12. The electrodes 14 may be formed of a metal, such as aluminum or copper. The electrodes 14 may be land-shaped areas designed for use in electric connection with the outside in the internal wiring of the semiconductor substrate 10. Alternatively, the electrodes 14 may be an exposed area of the internal wiring of the semiconductor substrate 10 at an opening of a passivation film 16 to be described later.

The electrodes 14 may be electrically connected to test pad 20 to be described later. In this case, all the electrodes 14 may be electrically connected to the test pad 20. Alternatively, some electrodes 14 may not be electrically connected to the test pad 20. For example, some electrodes 14 not electrically connected to the integrated circuit 12 may not be electrically connected to the test pad 20.

The semiconductor substrate 10 may have the passivation film 16. The passivation film 16 has an opening for exposing each electrode 14 (may be a center part of the electrode 14, for example). The passivation film may be formed of, for example, SiO2, SiN, polyimide resin, etc.

The semiconductor device according to the embodiment includes a resin layer 15 (see FIGS. 1B through 2B). The resin layer 15 is provided on the surface of the semiconductor substrate 10 on which the electrodes 14 are formed. The resin layer 15 may be provided on the passivation film 16, as shown in FIGS. 1C and 2A. The resin layer 15 includes a first surface 18, which faces the semiconductor substrate 10, and a second surface 19, which is on the other side of the first surface 18. The resin layer has a concave portion 17 formed thereon (see FIGS. 1C through 2B). The concave portion 17 is formed on the other side (the second surface 19) of the surface facing the semiconductor substrate 10. The concave portion 17 may be a concave portion that does not penetrate through the resin layer 15. Instead of the concave portion 17, a hole through the resin layer 15 may be provided. The concave portion 17 may be larger in outside dimensions than the electrode 14. In this case, the concave portion 17 may have a larger bottom in size than the electrode 14. When the hole through the resin layer 15 is provided, the hole may be larger in outside dimensions than the electrode 14. In this case, the hole has a larger bottom in outside dimension than the electrode 14. The resin layer 15 may have a stress relief function. The resin layer 15 may be called a stress relief layer. The material of the resin layer 15 is not limited. For example, a resin, such as polyimide resin, silicone-modified polyimide resin, epoxy resin, silicone-modified epoxy resin, benzocyclobutene (BCB), and polybenzoxazole (PBO), may be used as the material of the resin layer 15.

The semiconductor device according to the embodiment has the plural test pads 20 electrically connected to the plural electrodes 14, as shown in FIGS. 1B through 2B. The test pad 20 may be an area for conducting an electrical property test by touching it with a probe 35, as shown in FIG. 3. In this test process, for example, the electrical properties of the integrated circuit 12 may be tested. The test pad 20 may be larger in outside dimensions than the electrode 14 (see FIG. 1B). The test pad 20 is formed inside the concave portion 17. The test pad 20 may be formed on the bottom of the concave portion 17, as shown in FIG. 2B. The test pad 20 may be enclosed with an inside wall of the concave portion 17. At least part of the surfaces of the test pad 20 may be concave relative to the second surface 19 of the resin layer 15. The array of the test pads 20 is not limited. The plural test pads 20 may be arranged in a straight or staggered shape. Alternatively, the plural test pads 20 may be arranged randomly without any regularity. The test pad 20 may be provided between a land 30 to be discussed later and the electrode 14.

The test pads 20 may be electrically connected to the land 30 to be described later. In this case, all the test pads 20 may be electrically connected to any one of the lands 30. The test pads 20 may include pads not electrically connected to any land 30.

The semiconductor device according to the embodiment has the lands 30 electrically connected to any one of the test pads 20. The land 30 may be a part of the semiconductor device in which an external terminal 40 to be described later is mounted. The land 30 may be provided on the resin layer 15 (on the second surface 19 of the resin layer is). The land 30 may be provided between the test pad 20 and the electrode 14. The land 30 is electrically connected to any one of the electrodes 14. In the semiconductor device according to the embodiment, all the lands 30 may be electrically connected to any one of the test pads 20. Incidentally the semiconductor device may include lands electrically connected to any one of the electrodes 14 but not electrically connected to any test pad 20.

The semiconductor device according to the embodiment includes wirings 22 and 32 electrically connected to the test pad 20, as shown in FIGS. 1B and 1C. In this case, the wiring 22 may be a wiring that electrically connects the test pad 20 and the electrode 14. The wiring 32 may be a wiring that electrically connects the test pad 20 and the land 30. The wirings 22 and 32 are formed such that they go through on the second surface 19 of the resin layer 15. The wirings 22 and 32 are narrower in width than the test pad 20.

In the semiconductor device according to the embodiment, the wirings 22 and 32 may be drawn from the test pad 20 and electrically connected to the electrode 14 and the land 30, respectively, as shown in FIGS. 1B and 1C. However the invention is not limited to this configuration. For example, the two wirings may be drawn from the land 30 and connected to the electrode 14 and the test pad 20, respectively. Alternatively, the two wiring may be drawn from the electrode 14 and connected to the test pad 20 and the land 30, respectively.

The test pad 20, land 30, and wirings 22 and 32 may be collectively called a conductive pattern 25. The method of forming the conductive pattern 25 is not limited. For example, the conductive pattern 25 may be formed by patterning a conductive layer formed on the semiconductor substrate 10. The shape of the conductive pattern 25 may be controlled by adjusting the shape of a resist layer used in the patterning process.

The semiconductor device according to the embodiment may have an external terminal 40 provided on the land 30, as shown in FIGS. 1C and 2A. The external terminal 40 is electrically connected to the land 30. For example, the external terminal 40 may be formed of solder.

The semiconductor device according to the embodiment may have a resist layer 42, as shown in FIGS. 1C and 2A. The resist layer 42 may have an opening 44 for exposing the test pad 20 formed thereon. The resist layer 42 may be formed so as to cover the electrode 14 and wirings 22 and 32. The resist layer 42 may have an opening 46 for exposing the land 30 formed thereon. The opening 46 may be provided so as to overlap the central region of the land 30. The external terminal 40 may be electrically connected to the land 30 using the opening 46.

The semiconductor device according to the embodiment may include a reinforcement layer 50 for reinforcing roots of the external terminal 40, as shown in FIG. 1C. A part of the reinforcement layer 50 may be formed so as to fill the opening 44 of the resist layer 42. That is, the exposed portion of the test pad 20 at the opening 44 of the resist layer 42 may be covered with the reinforcement layer 50. The portion of the reinforcement for covering the exposed portion of the test pad 20 at the opening 44 of the resist layer 42 may be called a coating portion 52.

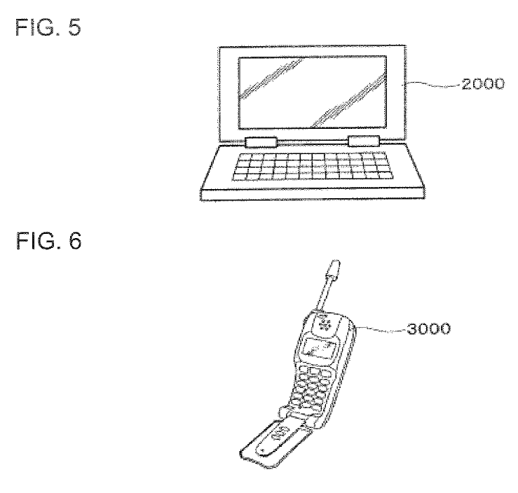

The semiconductor device according to the embodiment may be configured as described above. However, the semiconductor device according to the embodiment may refer to a semiconductor device having neither the resist layer 42 nor the external terminal 40 formed thereon. Alternatively, one of pieces into which the semiconductor device 1 is divided may be called a semiconductor device 2. FIG. 4 shows a circuit board 1000 on which the semiconductor device 2 is mounted. As an electronic device that includes the semiconductor device 1, FIG. 5 and FIG. 6 show a notebook PC 2000 and a mobile phone 3000, respectively.

According to the invention, it is possible to provide a semiconductor device which can be miniaturized and on which a reliable electrical property test can be easily conducted. Hereafter, this effect is described.

The probe test is known as a method of testing the electric properties of a semiconductor device. This is an electrical testing method in which a test needle called probe is made to touch the test object in order to test the electrical properties of the object.

When testing the electrical properties of a semiconductor device with a probe, the probe must be made to touch the electrode. However, there is a limitation in the accuracy with which the probe position can be controlled. Consequently the electrode must be formed in a certain or larger size to reliably conduct a probe test using an electrode. However, it is expected that the limitation in the electrode size prevents miniaturization of the semiconductor device (semiconductor chip). As integrated circuits increase the packing density, the wiring inside the semiconductor chip is increasingly difficult. However, making the electrode smaller would facilitate the wiring inside the semiconductor chip, allowing an electrically reliable semiconductor chip to be designed.

Touching the external terminal (land) with a probe can be considered as a method of testing the electrical properties of a semiconductor device with a probe. However, it is not possible to test electrodes not connected to any external terminal (land) by this method. It is also expected that making the probe push against the external terminal applies force to the external terminal, resulting in breakage or dropout of the external terminal.

On the other hand, the semiconductor device 1 allows the probe to touch the test pad 20 in order to test the electrical properties. This eliminates the need to use the electrode 14 for the electrical property test. Thus, even though the electrode 14 is miniaturized, it is possible to conduct an electrical property test. Miniaturization of the electrode 14 allows miniaturization of the semiconductor device (semiconductor chip). That is, according to the invention, it is possible to provide a semiconductor device that has miniaturization potential as well as electrical reliability, because it is possible to conduct an electrical property test even though the electrode 14 is miniaturized. In particular, making the test pad 29 larger than the electrode 14 allows easily conducting an electrical property test. Forming the test pad 20 inside the concave portion 17 of the resin layer 15 can prevent the probe from coming off from the test pad 20 when the probe test is conducted. This allows conducting a reliable electrical property test. According to the invention, it is possible to conduct an electrical property test on a semiconductor device provided with the external terminal 40, without using the external terminal 40. Therefore, it is possible to conduct an electrical property test without damaging the external terminal 40 as well as to conduct an electrical property test on the electrode 14 not electrically connected to the external terminal 40 (land 30). The probe test on the semiconductor device may be conducted in any stage after the process of forming the test pad 20 (conductive pattern 25) is complete. For example, the probe test may be conducted on a semiconductor device in which the resist layer 42 is yet to be formed. Alternatively, the probe test may be conducted on a semiconductor device having the resist layer 42. In this case, the opening 44 of the resist layer 42 may be used to conduct the probe test. Alternatively, the probe test may be conducted on a semiconductor device having the external terminal 40. Alternatively, the probe test may be conducted on a semiconductor device having the reinforcement layer 50 (coating portion 52). In this case, the coating portion 52 may be formed of a material softer than the resist layer 42. By doing this, the probe test is easily conducted even after the coating portion 52 is formed. Conducting the probe test on a semiconductor device having the reinforcement layer 50 formed thereon allows conducting the probe test on a semiconductor device that is close to a product level. Thus, a more reliable electrical property test can be conducted. In this case, the coating portion 52 may be formed of a transparent material. The reinforcement layer 50 may be formed so as to have a concave portion that overlaps each other with the test pad 20. Using these configurations allows the position of the test pad 20 to be easily identified even after the process of forming the reinforcement layer 50 or the coating portion 52 is complete. This makes it possible to implement the test process with efficiency and reliability.

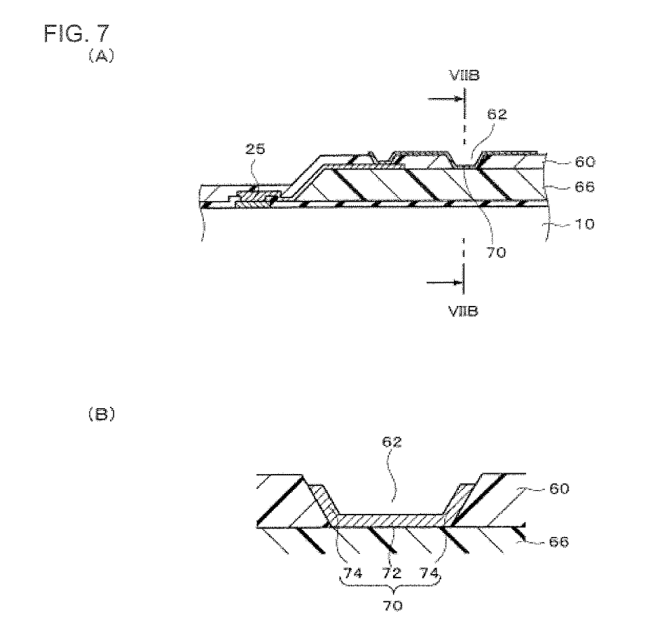

FIGS. 7A and 7B show semiconductor devices according to a modification of the embodiment of the invention.

The semiconductor device according to the embodiment may include the resin layer 60 and a resin layer 66, as shown in FIG. 7A. The resin layers 60 and 66 may be laminated. The resin layer 60 may have a hole 62 formed thereon. The hole 62 may be a hole that penetrates through the resin layer 60. That is, the hole 62 may be a hole that partially exposes the resin layer 66.

The semiconductor device according to the embodiment includes a test pad 70, as shown in FIG. 7B. The test pad 70 may include a bottom portion 72 and a sidewall 74 that encloses the bottom portion 72. The bottom portion 72 may be formed on the bottom of the hole 62. That is, the bottom portion 72 may be formed on the resin layer 66 formed beneath the resin layer 60. The sidewall 74 may be formed on the inside wall surface of the hole 62. The bottom portion 72 and the sidewall 74 may be integrally formed. In the semiconductor device according to the embodiment, the sidewall 74 may be formed inside the hole 62. Note that in the semiconductor device according to the embodiment, a part of the sidewall 74 may be formed so as to reach outside of the hole 62. Even in this case, the probe can be prevented from coming off from the bottom portion 72 because the bottom portion 72 is enclosed by the sidewall 74. This allows conducting a highly reliable electrical property test. In the embodiment, only the bottom portion 72 may be called the test pad.

This invention is not limited to the embodiment mentioned above, and various modifications can be made. For example, the invention includes a substantially identical configuration to the configuration described in the embodiment (for example, an identical configuration in function, method, and result, or an identical configuration in objective and effect). The invention also includes a configuration in which a not-essential part of the configuration described in the embodiment is replaced The invention also includes a configuration that can exert an identical effect or achieve an identical objective to the configuration described in the embodiment. The invention also includes a configuration in which a well-known technology is added to the configuration described in the embodiment.

What is claimed is:

1. A semiconductor device, comprising:
a semiconductor substrate having an electrode;
a resin layer provided on the surface of the semiconductor substrate on which the electrode is formed and having a concave portion formed on a second surface on the other side of a first surface facing the semiconductor substrate;
a test pad electrically connected to the electrode and formed inside the concave portion;
wiring electrically connected to the test pad, going through on the second surface of the resin layer, and narrower in width than the test pad; and
a land electrically connected to the test pad and having an external terminal formed thereon.

2. A semiconductor device comprising:
a semiconductor substrate having an electrode;
a resin layer provided on the surface of the semiconductor substrate on which the electrode is formed and having a hole on a second surface on the other side of a first surface facing the semiconductor substrate;
a test pad electrically connected to the electrode and formed inside the hole;
wiring electrically connected to the test pad, going through on the second surface of the resin layer, and narrower in width than the test pad; and
a land electrically connected to the test pad and having an external terminal formed thereon.

3. The semiconductor device according to claim 1, wherein the test pad is larger in outside dimensions than the electrode.

4. The semiconductor device according to claim 1, further comprising:
a resist layer having an opening for exposing the test pad formed thereon.

5. The semiconductor device according to claim 4, further comprising:
a coating portion for covering an exposed portion of the test pad at the opening.

6. The semiconductor device according to claim 1, wherein the land is provided between the test pad and the electrode.

7. The semiconductor device according to claim 1, wherein the test pad is provided between the land and the electrode.
